(19) United States
(12) Patent Application Publication
(10) Pub. No.: US 2012/0227793 A1
(43) Pub. Date: Sep. 13, 2012

(54) SEALING THE EDGES OF PHOTOVOLTAIC MODULES

(75) Inventors: Heinz Meier, Zurich (CH); Hans Rohrer, Sachseln (CH); Stefan Keiser, Schwarzenberg (CH); Josef Lussi, Zermatt (CH); Norman Blank, Ruschlikon (CH)

(73) Assignee: SIKA TECHNOLOGY AG, Baar (CH)

(21) Appl. No.: 13/504,770

(22) PCT Filed: Nov. 2, 2010
(86) PCT No.: PCT/EP10/66639

§ 371 Date: May 15, 2012

(30) Foreign Application Priority Data
Nov. 4, 2009 (EP) 09175021.6

(51) Int. Cl. H01L 31/048; H01L 31/18

(52) U.S. Cl. 136/251; 438/66; 257/E31.117

(57) ABSTRACT

A method for sealing the edges of photovoltaic modules, including the steps of i) providing a photovoltaic module by applying at least one photovoltaic laminate to a carrier; ii) treating the photovoltaic module produced in step i) along the edge region of the photovoltaic laminate by means of a plasma pretreatment or by flame application by means of a gas flame, such that both the edge region of the photovoltaic laminate and, at least partially, the carrier is detected by the plasma pretreatment or the flame application; and iii) applying a sealing mass at least partially to the pretreated location, wherein the sealing mass is a silicone composition or a composition based on silane-terminated poly(meth)acrylates.

### TECHNICAL FIELD

The invention relates to the field of sealing the edges of photovoltaic modules.

### PRIOR ART

Sealing the edges of photovoltaic modules is known in the art, and serves to protect the adhesive layers inside the photovoltaic laminate and the adhesive layer between photovoltaic laminate and substrate. Sealing compounds on a polyamide base are used for sealing the edges.

Sealing compounds on a polyamide base exhibit only limited adhesion both to substrate materials, particularly to roof sheeting, and to top layers of photovoltaic laminates, for example those made of ETFE. As a result of a soiled application, mechanical stress during installation of the photovoltaic module, or the effects of weather during the deployment phase, the edge sealing can become at least partially separated from the edge of the photovoltaic laminate. This permits water, particularly rain water, to directly reach the edge of the photovoltaic laminate, and over the longer term this water can damage the adhesive layer between roof sheeting and photovoltaic laminate, or can lead to delaminations within the multilayered photovoltaic laminate.

### DESCRIPTION OF THE INVENTION

The problem addressed by the present invention is therefore that of providing a method for sealing the edges of photovoltaic modules which overcomes the disadvantages of the prior art and results in photovoltaic modules that are securely and permanently sealed. Surprisingly, it has been found that the method according to claim 1 solves this problem.

Applying the method according to the invention, it is possible to use silicone compositions or compositions based on silane-terminated poly(meth)acrylates for sealing the edges of photovoltaic modules, even though compositions of this type are known to exhibit poor adhesion results on the type of substrates that are used in the production of photovoltaic modules. Surprisingly, the method according to the invention is also suitable for sealing the edges of flexible photovoltaic laminates on flexible substrates, even though with arrangements of this type, the load on the edge seal, particularly resulting from turning and bending of the photovoltaic module, is particularly high.

Moreover, the use of the method according to the invention, particularly when used with preferred two-component sealing compounds, permits the sealing of the edges of photovoltaic modules in very short cycle times.

A further significant advantage of the method according to the invention or of the photovoltaic module according to the invention is the particular UV stability of the sealing compounds that are used, which allows a reliable sealing of the photovoltaic module for the entire guaranteed service life of the photovoltaic laminate.

Further aspects of the invention are the subject matter of additional independent claims. Particularly preferred embodiments of the invention are the subject matter of the dependent claims.

### BRIEF DESCRIPTION OF THE DRAWINGS

Embodiment examples of the invention will be specified in greater detail in reference to the drawings. In the various figures, the same elements are identified by the same reference symbols. Of course, the invention is not limited to the illustrated and described embodiment examples.

The drawings show:

FIG. 1 a schematic illustration (cross-section) of a photovoltaic laminate;

FIG. 2 a schematic illustration (cross-section) of a photovoltaic module consisting of photovoltaic laminate and substrate during plasma pretreatment;

FIG. 3 a schematic illustration (cross-section) of a photovoltaic module with sealed edges;

FIG. 4 a schematic illustration (cross-section) of a photovoltaic module with sealed edges;

FIG. 5 a schematic illustration (cross-section) of a photovoltaic module with sealed edges;

FIG. 6 a schematic illustration (cross-section) of a photovoltaic module with an extended top layer and sealed edges;

FIG. 7 a schematic illustration (cross-section) of a photovoltaic module with an extended top layer and a sealed edge in an edge fold;

FIG. 8 a schematic illustration (view from the top) of a section of a photovoltaic module;

FIG. 9 a schematic illustration (view from above) of a photovoltaic module.

In the figures, only those elements that are essential for the immediate understanding of the invention are illustrated.

### METHODS FOR IMPLEMENTING THE INVENTION

The present invention relates to a method for sealing the edges of photovoltaic modules, comprising the following steps:

i) preparing a photovoltaic module 12 by applying at least one photovoltaic laminate 1 to a substrate 8;

ii) pretreating the photovoltaic module produced in step i) along the edge area of the photovoltaic laminate by means of a plasma pretreatment or by flame treatment using a gas flame, such that both the edge area of the photovoltaic laminate and, at least partially, the substrate are acted on by the plasma pretreatment or by the flame treatment;

iii) applying a sealing compound 9 at least in part to the pretreated site, wherein the sealing compound is a silicone composition or a composition based on silane-terminated poly(meth)acrylates.

In the present document, the term “photovoltaic laminate” refers to one or several photovoltaic cells, i.e., electrical components for converting radiant energy, particularly sunlight, into electrical energy, which are covered over the entire surface of at least one side with a layer of plastic. Generally, a photovoltaic laminate comprises one or more layers over the full surface of both sides.

In the present document, the term “photovoltaic module” refers to an arrangement of one or more photovoltaic laminates, which are disposed at or on any substrate and which are used to obtain solar power.

In the present document, substance names beginning with “poly”, such as polyol, refer to substances that, technically, contain two or more per molecule of the respective functional groups contained.

In the present document, the term “polymer” comprises a collective of chemically uniform macromolecules, which nevertheless differ with respect to degree of polymerization, molar mass, and chain length, said collective being produced by way of a polyreaction (polymerization, polyaddition, polycondensation). However, the term also comprises derivatives of such a collective of macromolecules from polyreactions, in other words, compounds which have been obtained by conversions, such as additions or substitutions, of functional groups to predefined macromolecules, and which can be chemically uniform or chemically non-uniform. The term further comprises so-called prepolymers, in other words, reactive oligomeric preadducts, the functional groups of which are involved in synthesizing macromolecules.

The photovoltaic laminate comprises one or several photovoltaic cells. The design and the structure of cells of this type are well known to a person skilled in the art. In a preferred photovoltaic laminate, the layer with the photovoltaic cell or cells is provided on both sides, over the entire surface, with at least one additional layer. These additional layers serve primarily to protect the cells against mechanical effects or damaging environmental influences.

The photovoltaic laminate preferably comprises a plurality of plastic layers on both sides of the photovoltaic cells. These plastic layers can be made of the same material or of different materials. The layers can also be formed as layers with different layer thicknesses.

More particularly, the photovoltaic laminate comprises a layer of an at least partially halogenated polymer as the uppermost plastic layer toward the outside (top layer), i.e., that plastic layer which is directly exposed to environmental influences. The halogenated polymer preferably involves an at least partially fluorinated polymer or a copolymer of fluorinated monomers with non-fluorinated monomers. More particularly, it involves polytetrafluoroethylene (PTFE) or ethylene tetrafluoroethylene (ETFE), preferably ETFE. These materials are particularly well suited to the top layer, because, on the one hand, they exhibit a high resistance to chemicals, making them particularly resistant to environmental influences and, on the other hand, because they exhibit highlight and UV transmissivity.

Next to the described top layer, additional plastic layers of the photovoltaic laminate consist, for example, of polyolefins, polyethers, polyesters, polycarbonates, poly(meth)acrylates, or other, optionally substituted polyhydrocarbons. Preferred materials are polyethylene, polypropylene, polyethylene terephthalate (PET), and ethyl vinyl acetate (EVA). These additional plastic layers can also be formed differently and can exhibit different functions. Moreover, the photovoltaic laminate typically comprises an additional layer, which serves as the substrate for the photovoltaic coating, and is therefore located directly behind the layer having the photovoltaic cells. This layer can also be made of a plastic or of metal. If a metal layer is involved, it is particularly made of stainless steel.

The entire photovoltaic laminate exhibits a layer thickness ranging from 0.5 to 5 mm, particularly from 2 to 3 mm, with this layer thickness being distributed among the various layers of the photovoltaic laminate.

Particularly preferably, the photovoltaic laminate involves a flexible photovoltaic laminate. Such a laminate offers the advantage that it can even be applied to uneven surfaces or can be shaped to a certain degree for a specific application.

FIG. 1 shows, by way of example, a schematic construction of a photovoltaic laminate 1, consisting of the following layers from top to bottom or from outside to inside: top layer 3 of ETFE; layer of EVA 4; layer comprising photovoltaic cells 2; substrate for the photovoltaic coating 7; layer of PE 5; layer of PET 6; and layer of PE 5.

The substrate to which the photovoltaic laminate is applied can involve any type of substrate. More particularly, however, it involves a flexible substrate, since this offers the already-described advantages, particularly in connection with a flexible photovoltaic laminate.

Preferably, the substrate involves a membrane, particularly a plastic sealing sheet. Plastic sealing sheets of this type are typically used for external sealing of roof and façade constructions, and are characterized by good sealing properties, even under high water pressure, and by good values for tear propagation and perforation tests, which is particularly advantageous under mechanical loads at construction sites.

The advantage of a photovoltaic module consisting of a flexible photovoltaic laminate and a plastic sealing sheet as a substrate is that it can be installed like a conventional plastic sealing sheet, for example like a roofing sheet. A further advantage is that a photovoltaic module of this type can be installed geometrically true even on uneven surfaces, for example on an arched roof.

In flexible photovoltaic modules that are correspondingly constructed from a flexible photovoltaic laminate and a flexible substrate, the method according to the invention has proven particularly advantageous. The reason for this is that, particularly in the case of flexible photovoltaic modules, the load on the edge seal, particularly as a result of turning and bending of the photovoltaic module, is particularly high.

The substrate preferably involves a polyolefin substrate or a polyvinyl chloride substrate. These two materials are widely used in manufacturing plastic sealing sheets. The most highly preferred substrate materials are polyethylene (PE), such as high-density polyethylene (HDPE), medium-density polyethylene (MDPE) and low-density polyethylene (LDPE), polyethylene terephthalate (PET), polystyrene (PS), polyvinyl chloride (PVC), polyamide (PA), EVA, chlorosulfonated polyethylene, thermoplastic elastomers having an olefin base (TPE-O, TPO), ethylene propylene diene rubber (EPDM), polyisobutylene (PIB), and mixtures thereof.

The photovoltaic laminate can be attached in any way to the substrate. More particularly, the photovoltaic laminate is glued to the substrate. The photovoltaic laminate is preferably glued to the substrate by means of hot melt or warm melt adhesive. More particularly, the photovoltaic laminate is glued to the substrate using a hot melt adhesive having a polyurethane base.

As needed, a compensation layer can be arranged between the photovoltaic laminate and the substrate, which layer compensates for stresses resulting from a displacement of the photovoltaic laminate in relation to the substrate, thereby preventing the separation of the photovoltaic laminate from the substrate. Such stresses can result from mechanical loads or are the result of displacements caused by different linear temperature coefficients of expansion of the photovoltaic laminate and the substrate. The latter is the case particularly with intense solar radiation or with major temperature fluctuations.

The compensation layer involves a foamed layer, for example, made of a thermoplastic material such as a thermoplastic elastomer. Preferably, the compensation layer involves a layer of a foamed, elastic material.

It is further possible for the photovoltaic laminate to be glued to the substrate by means of a foamed adhesive, in place of a separate compensation layer.

The photovoltaic module produced in step i) of the method according to the invention is pretreated by means of plasma pretreatment or flame treatment using a gas flame.

In plasma pretreatment, the photovoltaic module produced in advance is treated along the edge area of the photovoltaic laminate with a plasma. As the gas, which in this case is present in the plasma state, various gases or gas mixtures can be used. The energy required by the gas to transition to the plasma state can also be supplied in a different manner.

It is also possible, and can even be advantageous, to add additives, such as silanes, to the gas in order to achieve a particularly adhesion-friendly pretreatment.

The plasma pretreatment preferably involves air plasma pretreatment at atmospheric pressure.

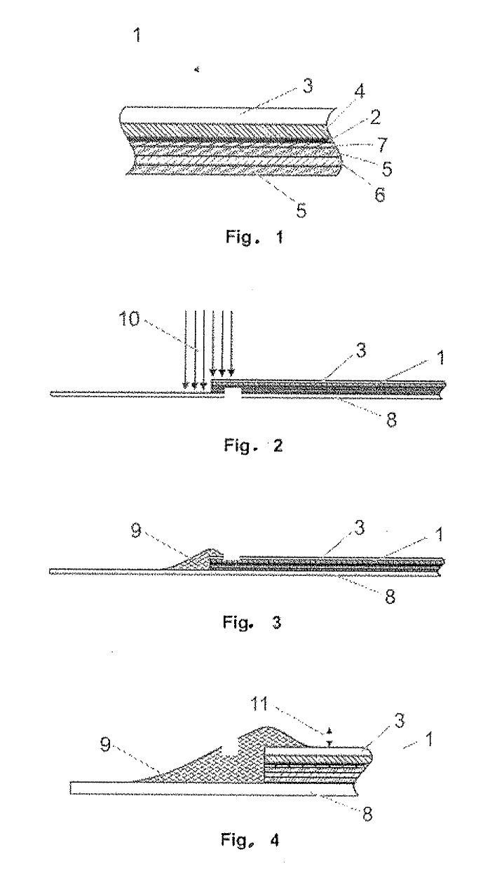

FIG. 2 illustrates, by way of example, the schematic construction of a photovoltaic module consisting of a photovoltaic laminate 1 with the top layer being made of ETFE 3, which is glued to a plastic sealing sheet. The arrows pointing toward the edge area of the photovoltaic laminate represent a plasma jet 10 for plasma pretreatment, which acts on both this edge area and, at least partially, the plastic sealing sheet.

In the flame treatment using a gas flame, the previously produced photovoltaic module is exposed along the edge area of the photovoltaic laminate to the direct effects of a gas flame for a short period of time. The duration of the flame treatment must be chosen such that the photovoltaic module or the substrate will not be damaged thereby.

Suitable as a gas for the flame treatment are propane or butane, for example, wherein the gas flame is operated particularly with excess oxygen, in order to optimally pretreat the surface.

The photovoltaic module is preferably pretreated with plasma. Plasma pretreatment offers the advantage over flame treatment that better adhesion results are achieved and that the risk of damage to the photovoltaic module or to the substrate by the gas flame is lower.

To achieve an optimum adhesion of the sealing compound to the photovoltaic module, it is advantageous to apply the sealing compound to the site of pretreatment within 4 weeks, particularly within 2 weeks, preferably immediately after plasma pretreatment or after flame treatment.

It is further important to the present invention that the entire area to which the sealing compound is to be applied be acted on by the plasma pretreatment or by the flame treatment.

The sealing compound can be applied to the photovoltaic module manually or in an automated process by means of a robot. More particularly, the sealing compound is applied mechanically.

The sealing compound can be applied in a different form, so that seals with different cross-sectional shapes result.

FIGS. 3 to 5 illustrate two differently applied sealing compounds, by way of example, showing the cross-sectional shapes thereof. The sealing compound 9 is preferably applied such that it covers both the edge area of the photovoltaic laminate 1 and/or the top layer 3 of the photovoltaic laminate and a part of the substrate 8. More particularly, the sealing compound is applied such that the height 11 by which the sealing compound projects beyond the photovoltaic laminate is as small as possible with optimum sealing. More particularly, this height 11 is no greater than 3 mm, preferably no greater than 1 mm. If the sealing compound projects too far beyond the photovoltaic laminate, said laminate can offer various disadvantages. For example, in this case, even with horizontal or slightly inclined photovoltaic modules, rain water is prevented from flowing off, so that there is standing water on the photovoltaic module. In the case of photovoltaic modules that can be walked on, this results in increased danger of slippage. A further disadvantage of sealing compound that projects too high on traversable systems is that in this case the sealing compound can be damaged more easily.

In certain cases, it is also possible, and can even be advantageous, for the sealing compound 9, as illustrated in FIG. 5, to cover only the intersecting edge of the photovoltaic laminate 1 and a part of the substrate 8. Because in this case the adhesive surface of the sealing compound is limited to the intersecting surface of the photovoltaic laminate 1 or of the top layer 3, the pretreatment of the edge area of the photovoltaic laminate should be oriented such that it also acts on the area of the intersecting edge.

It is also possible for the top layer 3 of the photovoltaic laminate I to be formed extended, and for the sealing compound 9, as illustrated in FIG. 6, to cover the edge area of the top layer 3 and the substrate 8.

In this case, it is also conceivable for the substrate 8 to be folded over the edge area of the photovoltaic laminate or over the edge area of the top layer 3, and for the sealing compound 9 to then be applied in the resulting edge fold. This embodiment is illustrated in FIG. 7.

The sealing compound preferably involves a silicone composition or a composition based on silane-terminated poly(meth)acrylates.

In this case, silicone compositions are typically understood as compositions based on polydiorganosiloxanes.

Suitable as a silicone composition are one- or two-component, moisture-hardening silicone compositions, such as are frequently used in window or façade construction. Such silicone compositions are commercially available, for example from Sika Schweiz AG, under the name Sikasil®.

Suitable as one-component, moisture-hardening silicone compositions are, for example, compositions based on alkoxy-, acetoxy-, or ketoxime-group-terminated polydiorganosiloxanes, comprising additional constituents, as are described in what follows as “additional constituents” in component A in the two-component silicone compositions, along with suitable cross-linking agents and catalysts.

For example, suitable one-component, moisture-hardening silicone compositions are described as component A in the European patent application with application number 08172783.6, the full disclosure of which is herewith included by way of reference.

Preferred one-component, moisture-hardening silicone compositions are described, for example, in patent application WO 2008/025812 A1, the full disclosure of which is herewith included by way of reference.

Furthermore, suitable one-component, moisture-hardening silicone compositions are commercially available, for example from Sika Schweiz AG under the trade names Sikasil® AS-70, WS-605 S, WS-305 or SG-20.

Also suitable are one-component, moisture-hardening silicone compositions as have been mentioned above, which are combined during application with a component that contains water.

The component containing water typically comprises, in addition to water, at least one vehicle, which is selected from the group consisting of a polydiorganosiloxane, a softening agent, a thickening agent, and a filler.

Preferably, the nature of the vehicle is such that it acts as a thickener and binds water.

The water content of the component containing water especially lies within a range such that with the water that is present, 50 to 100% of all reactive groups in the composition can be brought to reaction.

With the application of such compositions, the one-component, moisture-hardening silicone composition is mixed with the component containing water, for example by stirring, kneading, rolling, etc., but particularly by means of a static mixer or a dynamic mixer, wherein the one-component, moisture-containing silicone composition comes into contact with the water, resulting in a cross-linking of the composition.

Silicone compositions of this type and the application thereof are described in detail, for example, in the European patent application with the application number 08172783.6, the full disclosure of which is herewith included by way of reference.

The sealing compound preferably involves a two-component sealing compound, particularly a two-component silicone composition. The advantage of a two-component sealing compound is the faster hardening of the composition, which permits a faster and therefore more economical production method.

Most preferably, the sealing compound involves a two-component silicone composition.

Suitable as a two-component silicone composition are particularly silicone compositions consisting of a component A and a component B.

Component A in this case comprises a hydroxyl-group-terminated polydiorganosiloxane, particularly a polydiorganosiloxane P of formula (I).

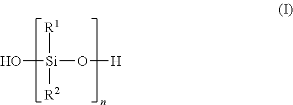

In this formula, the groups R¹ and R², independently of one another, stand for linear or branched, monovalent hydrocarbon groups with 1 to 12 C atoms, which optionally comprise one or several heteroatoms, and optionally comprise one or more C—C multiple bonds and/or optionally cycloaliphatic and/or aromatic constituents. More particularly, the groups R¹ and R² stand for alkyl groups having 1 to 5, particularly with 1 to 3 C atoms, preferably for methyl groups.

The index n is chosen such that at a temperature of 23° C. the polydiorganosiloxane P exhibits a viscosity of 10 to 500,000 mPa·sec, particularly of 6,000 to 100,000 mPa·sec.

Component A of the two-component silicone composition typically comprises additional constituents. Such additional constituents are particularly softening agents, such as trialkylsilyl-terminated polydialkylsiloxanes, particularly trimethylsilyl-terminated polydimethylsiloxanes, inorganic and/or organic fillers such as calcium carbonates, calcined kaolins, carbon black, high-dispersion silicic acids (primarily from pyrolysis processes) and flame-retardant fillers, such as hydroxides or hydrates, particularly hydroxides or hydrates of aluminum, preferably aluminum hydroxide, hardening accelerators, pigments, adhesion promoters such as organo-alkyoxysilanes, the organic groups of which are preferably substituted with functional groups, processing agents, rheological modifiers, stabilizers, dyes, inhibitors, heat stabilizers, antistatic agents, flameproofing agents, biocides, waxes, flow-control agents, thixotropic agents, and other customary raw materials and additives that are known to a person skilled in the art.

Component B of the two-component silicone composition comprises essentially at least one cross-linking agent for polydiorganosiloxanes and at least one catalyst K for cross-linking polydiorganosiloxanes.

More particularly, catalyst K involves a tin organic compound or a titanate.

Preferred tin organic compounds are dialkyltin compounds, such as are selected, for example, from the group consisting of dimethyltin di-2-ethylhexanoate, dimethyltin dilaurate, di-n-butyltin diacetate, di-n-butyltin di-2-ethylhexanoate, di-n-butyltin dicaprylate, di-n-butyltin di-2,2-dimethyloctanoate, di-n-butyltin dilaurate, di-n-butyltin distearate, di-n-butyltin dimaleate, di-n-butyltin dioleate, di-n-butyltin diacetate, di-n-octyltin di-2-ethylhexanoate, di-n-octyltin di-2,2-dimethyloctanoate, di-n-octyltin dimaleate, and di-n-octyltin dilaurate.

As titanates or organotitanates, compounds are identified which have at least one ligand bonded via an oxygen atom to the titanium atom. Suitable ligands bonded via an oxygen-titanium bond to the titanium atom are those selected from the group consisting of an alkoxy group, sulfonate group, carboxylate group, dialkyl phosphate group, dialkyl pyrophosphate group, and acetylacetonate group. Preferred titanates include tetrabutyl or tetraisopropyl titanate, for example.

Further suitable titanates comprise at least one multidentate ligand, also called a chelating ligand. More particularly, the multidentate ligand is a bidentate ligand.

Suitable titanates are available commercially, for example from the firm of DuPont, USA under the trade names Tyzor® AA, GBA, GBO, AA-75, AA-65, AA-105, DC, BEAT, and IBAY.

Of course, it s possible, or in certain cases is even preferable, to use mixtures of various catalysts.

As cross-linking agents for polydiorganosiloxanes, component B of the two-component silicone composition particularly contains a silane of formula (II).

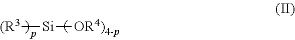

The group R³ in this case independently stands for a linear or branched, monovalent hydrocarbon group with 1 to 12 C atoms, which optionally comprises one or several heteroatoms, and optionally one or several C—C multiple bonds and/or optionally cycloaliphatic and/or aromatic constituents.

The group R⁴ independently stands for a hydrogen atom or for an alkyl group with 1 to 12 C atoms, or for a carbonyl group with 1 to 12 C atoms, or for an oxime group with 1 to 12 C atoms. More particularly, the group R⁴ stands for an alkyl group with 1 to 5, particularly 1 to 3 C atoms, preferably for a methyl group or for an ethyl group.

The index p stands for a value of 0 to 4, with the stipulation that if p stands for a value of 3 or 4, at least p-2 R³ groups comprise at least one group each that is reactive, particularly condensable, with the hydroxyl groups of the polydiorganosiloxane P, in other words, for example, a hydroxyl group. More particularly, p stands for a value of 0, 1 or 2, preferably for a value of 0.

Examples of suitable silanes of formula (II) are methyltrimethoxysilane, chloromethyltrimethoxysilane, ethyltrimethoxysilane, propyltrimethoxysilane, vinyltrimethoxysilane, methyltriethoxysilane, vinyltriethoxysilane, phenyltriethoxysilane, methyltripropoxysilane, phenyltripropoxysilane, tetramethoxysilane, tetraethoxysilane, tetra-n-propoxysilane, or tetra-n-butoxysilane. Particularly preferably, the silane of formula (II) involves vinyltrimethoxysilane or tetraethoxysilane or a mixture thereof.

Of course, any mixture of the above-named silanes can be used as the cross-linking agent for the two-component silicone composition.

In a large industrial system, the two components A and B are typically stored separately from one another in vats or drums, and are forced out during application, for example by means of geared pumps, and are mixed as described above.

Preferred two-component silicone compositions are described in detail, for example, in the European patent application, with application number 08169676.7, the full disclosure of which is herewith included by way of reference.

Furthermore, suitable two-component silicone compositions are commercially available from Sika Schweiz AG under the trade name Sikasil® AS, for example Sikasil® AS-785, or under the trade name Sikasil® WT, for example Sikasil® WT 485.

Additional suitable silicone compositions are those generally also known as silicone rubber. For example, one silicone rubber of this type is a two-component silicone composition consisting of a component A comprising a polydiorganosiloxane with unsaturated organic groups, particularly vinyl groups, and a component B comprising a silane having Si—H bonds. Platinum, palladium, or rhodium compounds are typically used as a catalyst for the addition cross-linking of a silicone rubber of this type.

Also conceivable is the use of a radically hardening polydiorganosiloxane, which also comprises unsaturated organic groups, more particularly, vinyl groups. Suitable as radical formers, then, are peroxides, peroxy esters, and the like, for example. Radically hardening silicone compositions can be formed as one-component or two-component. For example, one-component silicone compositions of this type comprise radical formers, which form radicals under the influence of heat or of electromagnetic radiation, particularly UV radiation. With the two-component, radically hardening silicone compositions, radical formation typically occurs by means of a catalyst, which is present in component B.

Compositions comprising at least one silane-terminated poly(meth)acrylate are a suitable composition based on silane-terminated poly(meth)acrylates, which can be obtained, particularly, by a hydrosilylation reaction of poly(meth)acrylates with terminal double bonds. This production method is described, for example, in U.S. Pat. No. 3,971,751 and U.S. Pat. No. 6,207,766, the disclosure of which is herewith included by way of reference.

Suitable silane-terminated poly(meth)acrylates are, for example, commercially available from the Kaneka Corporation, Japan, under the trade name Kaneka XMAP™.

Suitable compositions based on silane-terminated poly(meth)acrylates can be formed as one- or two-component compositions.

Suitable as two-component compositions based on silane-terminated poly(meth)acrylates are, typically, one-component, moisture-hardening compositions based on silane-terminated poly(meth)acrylates, which, as has already been described in reference to the silicone compositions, are combined during application with a component that contains water.

Preferred compositions based on silane-terminated poly(meth)acrylates are those having the type and constitution described in detail, for example, in the European patent application with application number 09161265.5, the full disclosure of which is herewith included by way of reference.

The present invention further relates to a photovoltaic module.

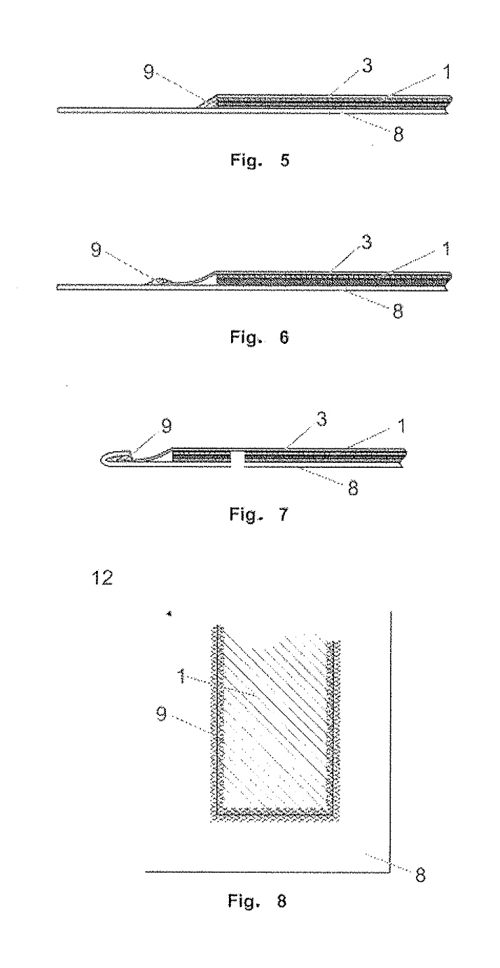

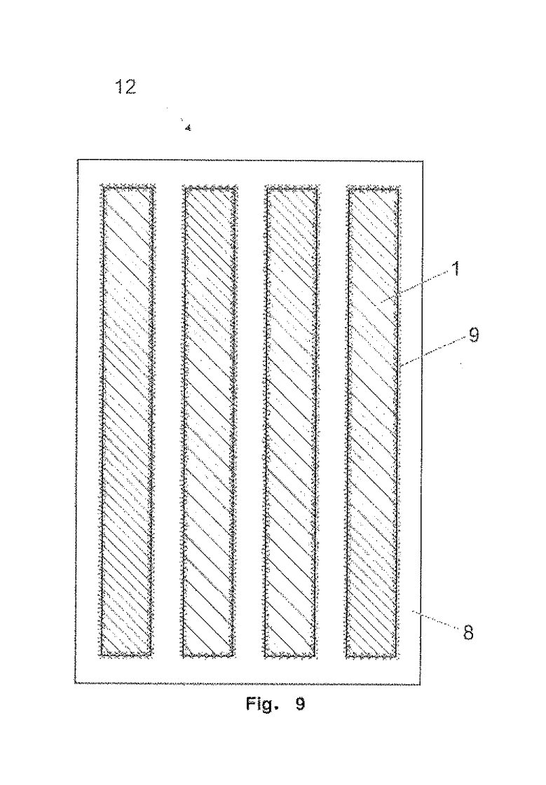

As is illustrated in FIGS. 8 and 9, the photovoltaic module 12 in this case comprises a substrate 8, to which a photovoltaic laminate 1 is attached, wherein the site of the edge area of the photovoltaic laminate is sealed with a sealing compound 9, and this sealing compound is a silicone composition or a composition based on silane-terminated poly(meth)acrylates. The substrate, the photovoltaic laminate and the sealing compound are of the type already described above.

More particularly, the photovoltaic module is a module like that which can be obtained from the above-described method.

The present invention further relates to the use of a silicone composition or a composition based on silane-terminated poly(meth)acrylates for sealing the edges of photovoltaic modules. More particularly, the composition used involves a composition like that already described above. The use of such compositions for sealing the edges of photovoltaic modules offers the advantage that these compositions have a very high UV stability.

Preferred is the use of a silicone composition, wherein this is a two-component silicone composition.

### EXAMPLES

In what follows, embodiment examples are described which will illustrate the described invention in greater detail. Of course, the invention is not limited to these described embodiment examples.

The adhesion of a two-component silicone composition to the surface of a photovoltaic laminate was tested. For this purpose, in a first step a photovoltaic laminate with a surface of RIFE, as is commercially available from the firm of United Solar Ovonic, LLC, USA (FIFE: Tefzel® ETFE from DuPont, USA), was pretreated with a plasma. The plasma was produced using an FG 3001 system from Plasmatreat GmbH, Germany (air pressure: 2 bar, 260 V, 2.8 A) and was applied via a nozzle from a distance of 8 mm. The photovoltaic laminate was advanced at a rate of approximately 150 mm/second.

Following the plasma pretreatment, a bead of a two-component silicone composition Sikasil® WT 485, commercially available from Sika Schweiz AG, was applied to each pretreated site using an application system from the company of Dosiplast, Switzerland, by means of a static mixer.

After 15 minutes at 23° C. and 50% relative humidity, an adhesion rate of 100% was established in the applied beads (100% cohesive fracture).

Following this test, the sample bodies were stored for a period of 6 weeks at 85° C. and 85% relative humidity, after which they exhibited no optical changes and no changes in adhesion (100% cohesive fracture).

Following the described tests, the sample bodies were stored for a period of 15 weeks in a 5% NaCl solution at 70° C. After this test as well, the sample bodies exhibited no optical changes and no changes in adhesion (100% cohesive fracture).

### LIST OF REFERENCE SYMBOLS

1 Photovoltaic laminate
2 Layer with photovoltaic cells
3 Top layer
4 Layer of EVA
5 Layer of PE
6 Layer of PET
7 Substrate for the photovoltaic coating
8 Substrate
9 Sealing compound
10 Plasma jet
11 Distance
12 Photovoltaic module

1. A method for sealing the edges of photovoltaic modules comprising the following steps:
i) preparing a photovoltaic module by applying at least one photovoltaic laminate to a substrate;
ii) pretreating the photovoltaic module produced in step i) along the edge area of the photovoltaic laminate by means of plasma pretreatment or flame treatment using a gas flame, such that both the edge area of the photovoltaic laminate and, at least partially, the substrate are acted on by the plasma pretreatment or by the flame treatment; and
iii) applying a sealing compound to at least part of the pretreated area, wherein the sealing compound is a silicone composition or a composition based on silane-terminated poly(meth)acrylates.

2. The method according to claim 1, wherein the photovoltaic laminate is a flexible photovoltaic laminate.

3. The method according to claim 1, wherein the photovoltaic laminate comprises a top layer made of an at least partially halogenated polymer.

4. The method according to claim 3, wherein the halogenated polymer is ethylene tetrafluoroethylene (ETFE).

5. The method according to claim 1, wherein the substrate is a flexible substrate.

6. The method according to claim 1, wherein the substrate is a membrane.

7. The method according to claim 1, wherein the substrate is a polyolefin substrate or a polyvinyl chloride substrate.

8. The method according to claim 1, wherein the sealing compound is a two-component silicone composition.

9. The method according to claim 1, wherein the pretreatment is carried out by plasma pretreatment.

10. The method according to claim 9, wherein the plasma pretreatment is an air plasma treatment at atmospheric pressure.

11. The method according to claim 1, wherein the photovoltaic laminate is glued to the substrate.

12. A photovoltaic module comprising a substrate, to which a photovoltaic laminate is applied, wherein the site of the edge area of the photovoltaic laminate is sealed with a sealing compound and the sealing compound is a silicone composition or a composition based on silane-terminated poly(meth)acrylates.

13. A photovoltaic module obtainable from the method of claim 1.

14. A method comprising sealing an edge of a photovoltaic module with a silicone composition or a composition based on silane-terminated poly(meth)acrylates.

15. The method according to claim 14, wherein the silicone composition is a two-component silicone composition.
